(19) United States
(12) Patent Application Publication
(10) Pub. No.: US 2026/0066618 A1
(43) Pub. Date: Mar. 5, 2026

(54) Graded Metal-Oxide Layers in Vertical Cavity Surface-Emitting Laser

(71) Applicant: II-VI Delaware, Inc., Wilmington, DE (US)

(72) Inventors: Julián Bueno Moragues, Wilmington, DE (US); Mirko Wolfgang Hoser, Zurich (CH); Paul David Maximilian Quandt, Zurich (CH)

(21) Appl. No.: 18/817,927

(22) Filed: Aug. 28, 2024

(51) Int. Cl. H01S 5/183

(52) U.S. Cl. CPC H01S 5/18313; H01S 5/18327; H01S 5/18377

(57) ABSTRACT

A vertical cavity surface-emitting laser (VCSEL) includes a stack of semiconductor layers including: a bottom Distributed Bragg Reflector (DBR); a cavity layer; a current confinement layer; and a top DBR. The top DBR comprises multiple pairs of alternating layers with different refractive indices, wherein a subset of the multiple pairs of alternating layers includes alternating layers of decreasing concentration of at least one metal from lower layers of the top DBR disposed closer to the cavity layer to upper layers of the top DBR disposed further from the cavity layer. The subset of the multiple pairs of alternating layers with the decreasing concentration of at least one metal from the lower layers of the top DBR to the upper layers of the top DBR have decreasing oxidation depths from a side surface of the top DBR. A method of forming the VCSEL is also disclosed.

### BACKGROUND

### 1) Field The present disclosure relates to a vertical cavity surface-emitting laser (VCSEL) and, more particularly, to a VCSEL having graded metal oxide layers and a method of forming said VCSEL.

### 2) Background

A fundamental part of a VCSEL is the DBR (Distributed Bragg Reflector) that provides the optical confinement necessary for laser emission. The VCSEL has two DBRs, one in the top part of the VCSEL (i.e., a top DBR) and the other at the bottom of the VCSEL (i.e., a bottom DBR).

The design of DBRs for a VCSEL needs to fulfill a number of optical, electrical, and mechanical properties. DBRs are typically made of multiple layers of AlGaAs with different concentrations. In an example, the layer sequence may comprise pairs of layers, for example, a layer of low refractive index material (e.g., AlₓGa₁₋ₓAs) followed by a layer of high refractive index material (e.g., Al_{y}Ga_{1-y}As), wherein x>>y, and, for example, without limitation, 0≤x≤0.15 and/or 0.885≤y≤0.965. This alternation continues for several pairs of layers.

Another requirement of the VCSEL is the current confinement necessary to achieve high bandwidths. This can be achieved using an oxide aperture, wherein one layer of the VCSEL with high aluminum content, disposed between the top and bottom DBRs, is oxidized to create a current confinement layer including the oxide aperture where the innermost central area is not oxidized.

The process of oxidizing the aluminum of the current confinement layer requires the sides of the current confinement layer to be exposed to an oxidizing agent during formation of the VCSEL. This oxidation process, however, also exposes the sides of the layers of, at least, the top DBR to the oxidizing agent which may lead to oxidation of the layers of the top DBR with high aluminum content. While the layers of the top DBR with low aluminum content (when present) may also experience oxidation, for the purpose of this disclosure the oxidation of these layers of the top DBR with low aluminum content will be assumed to be negligible.

If the aluminum content of the layers of the top DBR is constant, the oxidation depth of the layers of the top DBR with high aluminum content will be the same or very similar. The oxidized material of high aluminum content of the top DBR has different mechanical properties than the material of low (or no) aluminum content of the top DBR, which creates mechanical stress around the regions of oxidized material of high aluminum content of the top DBR. This stress is especially strong or pronounced at or adjacent edge(s) of the oxidized material, and even more if there is a sudden change of oxidation depth from one layer to the next, e.g., from a layer of high aluminum content to a layer having low (or no) aluminum content. Under these stress conditions, the layers of the top DBR having low (or no) aluminum content may exhibit dislocations that may present a risk to the performance and quality of the VCSEL.

### SUMMARY

To reduce the stress inside the top DBR and, thereby, improve the performance and quality of the VCSEL, the top DBR may have alternating layers of increasing aluminum concentration of a subset of the top or upper layers of the top DBR to the lower or bottom layers of the top DBR instead of a constant concentration throughout the layers of the top DBR. This may create a stair step or staircase profile of oxidation inside the top DBR, separating the oxidation fronts from the different layers and reducing the maximum strain. It may also avoid or eliminate abrupt changes of oxidation depth through the top DBR, due to the oxidation depth being progressive and smoother, eliminating points of high localized stress. This solution not only may reduce the stress inside the top DBR, but may also reduce the capacitance of the top DBR, allowing the VCSEL to achieve higher operating bandwidths.

Disclosed herein is a vertical cavity surface-emitting laser (VCSEL) including, a bottom Distributed Bragg Reflector (DBR); a cavity layer on the bottom DBR; a current confinement layer on a side of the cavity layer opposite the bottom DBR; and a top DBR on a side of the cavity layer opposite the bottom DBR, wherein the top DBR comprises multiple pairs of alternating layers with different refractive indices, wherein a subset of said multiple pairs of alternating layers includes alternating layers of increasing metal concentration from upper layers of the top DBR to bottom layers of the top DBR.

Also disclosed herein is a method of forming a vertical cavity surface-emitting laser (VCSEL) comprising: (a) forming a bottom Distributed Bragg Reflector (DBR); (b) forming a cavity layer on the bottom DBR; (c) forming on a side of the cavity layer opposite the bottom DBR a current confinement layer; and (d) forming on a side of the cavity layer opposite the bottom DBR a top DBR comprising multiple pairs of alternating layers with different refractive indices, wherein a subset of said multiple pairs of alternating layers includes alternating layers of increasing metal concentration from upper layers of the top DBR to bottom layers of the top DBR.

### BRIEF DESCRIPTION OF THE DRAWINGS

FIG. 1 is a schematic cross-section of an example VCSEL in accordance with the principles of the present disclosure;

FIG. 2 is an SEM image of a portions of a section of an example VCSEL in accordance with the principles of the present disclosure showing, among other things, graded metal-oxide layers;

FIG. 3 is schematic cross-section of another example VCSEL in accordance with the principles of the present disclosure;

FIG. 4 is schematic cross-section of yet another example VCSEL in accordance with the principles of the present disclosure; and

FIG. 5 is a method in accordance with the principles of the present disclosure.

### DETAILED DESCRIPTION

Various non-limiting embodiments will now be described with reference to the accompanying figures where like reference numbers correspond to like or functionally equivalent elements or features.

As used herein, spatial, or directional terms, such as “left,” “right,” “inner,” “outer,” “above,” “below,” “top,” “bottom,” and the like, relate to the disclosure as it is shown in the drawing figures. However, it is to be understood that the disclosure can assume various alternative orientations and, accordingly, such terms are not to be considered as limiting. Further, as used herein, all numbers expressing dimensions, physical characteristics, processing parameters, quantities of ingredients, reaction conditions, and the like, used in the specification and claims are to be understood as being modified in all instances by the term “approximately” or “about. ” Accordingly, unless indicated to the contrary, the numerical values set forth in the following specification and claims may vary depending upon the desired properties sought to be obtained by the present disclosure.

At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1 to 3.3, 4.7 to 7.5, 5.5 to 10, and the like. “A” or “an”refers to one or more.

As used herein, “coupled, ” “coupling, ” and similar terms refer to two or more elements that are joined, linked, fastened, connected, put in communication, or otherwise associated (e.g., mechanically, electrically, fluidly, optically, electromagnetically) with one another. In various examples, the elements may be associated directly or indirectly. As an example, element A may be directly associated with element B. As another example, element A may be indirectly associated with element B, for example, via another element C. It will be understood that not all associations among the various disclosed elements are necessarily represented. Accordingly, couplings other than those depicted in the figures may also exist.

As used herein, the phrase “at least one of,” when used with a list of items, means different combinations of one or more of the listed items may be used and only one of each item in the list may be needed. For example, “at least one of item A, item B, and item C” may include, without limitation, item A or item A and item B. This example also may include item A, item B, and item C, or item B and item C. In other examples, “at least one of” may be, for example, without limitation, two of item A, one of item B, and ten of item C; four of item B and seven of item C; and other suitable combinations.

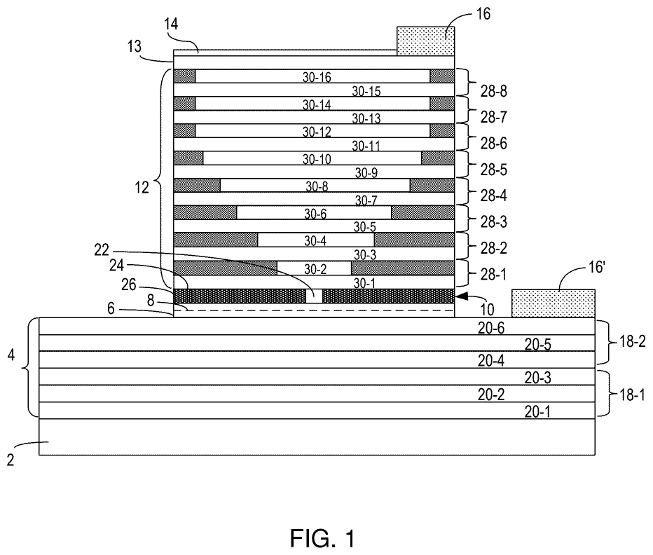

With reference to FIG. 1, an example VCSEL in accordance with the principles of the present disclosure may include a stack comprised of, from a bottom of to a top of the VCSEL, a substrate 2, a bottom DBR 4, a cavity layer 6 including an active region 8, a current confinement layer 10, a top DBR 12, a spreading layer 13, a passivation layer 14, and electrical contacts 16 and 16′ in electrical contact with the respective top DBR 12, e.g., a top surface of the top DBR 12, and the bottom DBR 4, e.g., a top surface of the bottom DBR 4.

In a non-limiting example, the substrate 2 may be formed of GaAs and the bottom DBR 4 may be formed of layers 18 of p or n-type AlGaAs.

In a non-limiting example, the bottom DBR 4 may comprise two layers 18-1 and 18-2 of p or n-type AlGaAs, wherein each layer 18 may comprise two or more sublayers 20 of the same or different thicknesses. In one non-limiting example, layer 18-1 may be comprised of multiple (e.g., five) alternating sublayers of p or n-type Al_{0.15}Ga_{1-0.15}As and p or n-type Al_{0.95}Ga_{1-0.95}As; and layer 18-2 may be comprised of multiple (e.g., five) alternating sublayers of p or n-type Al _{0.15}Ga_{1-0.15}As and p or n-type Al_{0.90}Ga_{1-0.90}As. The disclosure of the bottom DBR 4 comprising two layers 18-1 and 18-2, wherein each layer 18 comprises two or more sublayers 20, is not to be construed in a limiting sense since it is envisioned that the bottom DBR 4 may comprise any number of layers 18, wherein each layer 18 comprises any number of sublayers 20 as may be deemed suitable and/or desirable by one skilled in the art that enable the bottom DBR 4 to operate in a desired manner for a particular application.

As is known in the art: Al is Aluminum; Ga is Gallium; and As is arsenic. Throughout this disclosure, and notwithstanding any chemical nomenclature to the contrary, it is to be understood that in the various layers of AlGaAs, an increase (or decrease) of Al comes at the expense of a decrease (or increase) of Ga, i.e., AlₓGa₁₋ₓ or AlGa_{1-y}, while the concentration of As remains about the same.

In the example shown in FIG. 1, the bottom DBR 4 may include:
layer 18-1 which may be comprised of sublayers 20-1 through 20-3 of p or n-type AlGaAs of the same or different thicknesses; and
layer 18-2 which may be comprised of sublayers 20-4 through 20-6 of p or n-type AlGaAs of the same or different thicknesses.

These examples of a bottom DBR 4 are strictly for the purpose of example and are not to be construed in a limiting sense.

In an example, the cavity layer 6 may be disposed atop of (e.g., in direct contact with) the top layer 18-2 of the bottom DBR 4. In an example, the cavity layer 6 may comprise one or more instances of GaAs - InGaAs - GaAs sublayers disposed or sandwiched between multiple sublayers of AlGaAs. The one or more instances of sublayers of GaAs - InGaAs - GaAs may comprise the active region 8 of the cavity layer 6. As is known in the art, In is indium. The design of cavity layer 6 including active region 8 is known in the art and will not be further described in this disclosure for the purpose of simplicity.

In an example, the current confinement layer 10 may be disposed atop of (e.g., in direct contact with) the cavity layer 6 and between the top and bottom DBRs 12 and 4. The current confinement layer 10 may be comprised of a number of sublayers of AlGaAs. The current confinement layer 10 may comprise a region of low resistance to current flow 22 surrounded by a region of high resistance to current flow 24.

The current confinement layer 10 may be formed by oxidation of the Al and/or As of the sublayers of AlGaAs forming the current confinement layer 10 from the outside edge 26 of the current confinement layer 10. In response to this edge oxidation, the region of high resistance to current flow 24 forms inwardly from the outside edge 26 of the current confinement layer 10 to define the region of low resistance to current flow 22 which may not be (or substantially not be) oxidized. As a result of this oxidation, the region of high resistance to current flow 24 will block (or substantially block) a flow of electrical current between the top and bottom DBRs 12 and 4 while the region of low resistance to current flow 22 will allow the flow of electrical current to pass therethrough between the top and bottom DBRs 12 and 4. Stated differently, the current confinement layer 10 defines an oxide aperture wherein the innermost (un-oxidized) central area (i.e., the region of low resistance to current flow 22) is surrounded by the outer most oxidized area (i.e., the region of high resistance to current flow 24), whereupon electrical current flow between the top and bottom DBRs 12 and 4 will be directed or funneled through the region of low resistance to current flow 22.

In an example, the top DBR 12 may be disposed atop of (e.g., in direct contact with) the current confinement layer 10. The top DBR 12 may comprise layers 28-1 through 28-8 of p or n-type AlGaAs, wherein each layer 28 may comprise at least two sublayers 30 of the same or different thicknesses. In one non-limiting example, layer 28-1 may be comprised of multiple (e.g., between 2 and 6) alternating sublayers of p or n-type Al_{0.10}Ga_{1-0.10}As and p or n-type Al_{0.95}Ga_{1-0.95}As; layer 28-2 may be comprised of multiple (e.g., between 2 and 6) alternating sublayers of p or n-type Al_{0.10}Ga_{1-0.10}As and p or n-type Al_{0.94}Ga_{1-0.94}As; layer 28-3 may be comprised of multiple (e.g., between 2 and 6) alternating sublayers of p or n-type Al_{0.10}Ga_{1-0.10}As and p or n-type Al_{0.93}Ga_{1-0.93}As; layer 28-4 may be comprised of multiple (e.g., between 2 and 6) alternating sublayers of p or n-type Al_{0.10}Ga_{1-0.10}As and p or n-type Al_{0.91}Ga_{1-0.91}As; layer 28-5 may be comprised of multiple (e.g., between 2 and 6) alternating sublayers of p or n-type Al_{0.10}Ga_{1-0.10}As and p or n-type Al_{0.90}Ga_{1-0.90}As; layers 28-6 and 28-7 may each be comprised of multiple (e.g., between 2 and 6) alternating sublayers of p or n-type Al_{0.10}Ga_{1-0.10}As and p or n-type Al_{0.89}Ga_{1-0.89}As; and layer 28-8 may be comprised of multiple (e.g., 2 or 3) alternating sublayers of p or n-type Al_{0.89}Ga_{1-0.89}As. The number of sublayers of each layer 28 described above is strictly for the purpose of example and is not to be construed in a limiting sense.

In the example shown in FIG. 1, the top DBR 12 may include:
layer 28-1 which may be comprised of sublayers 30-1 and 30-2 of p or n-type AlGaAs of the same or different thicknesses;
layer 28-2 which may be comprised of sublayers 30-3 and 30-4 of p or n-type AlGaAs of the same or different thicknesses;
layer 28-3 which may be comprised of sublayers 30-5 and 30-6 of p or n-type AlGaAs of the same or different thicknesses;
layer 28-4 which may be comprised of sublayers 30-7 and 30-8 of p or n-type AlGaAs of the same or different thicknesses;
layer 28-5 which may be comprised of sublayers 30-9 and 30-10 of p or n-type AlGaAs of the same or different thicknesses;
layer 28-6 which may be comprised of sublayers 30-11 and 30-12 of p or n-type AlGaAs of the same or different thicknesses;
layer 28-7 which may be comprised of sublayers 30-13 and 30-14 of p or n-type AlGaAs of the same or different thicknesses; and layer 28-8 which may be comprised of sublayers 30-15 and 30-16 of p or n-type AlGaAs of the same or different thicknesses.

In this example, sublayers 30-1, 30-3, 30-5, 30-7, 30-9, 30-11, 30-13, and 30-15 may have the same concentration of Al, e.g., Al_{0.10}Ga_{1-0.10}As. Also in this example, sublayer 30-2 may have the highest concentration of Al, e.g., Al_{0.95}Ga_{1-0.95}As, of the sublayers 30; sublayer 30-4 may have the next highest concentration of Al, e.g., Al_{0.94}Ga_{1-0.94}As, of the sublayers 30; sublayer 30-6 may have the next highest concentration of Al, e.g., Al_{0.93}Ga_{1-0.93}As, of the sublayers 30; sublayer 30-8 may have the next highest concentration of Al, e.g., Al _{0.91}Ga_{1-0.91}As, of the sublayers 30; and sublayer 30-10 may have the next highest concentration of Al, e.g., Al_{0.90}Ga_{1-0.90}As, of the sublayers 30. Finally, sublayers 30-12, 30-14 and 30-16 may all have the same concentration of Al, e.g., Al_{0.89}Ga_{1-0.89}As, of the sublayers 30, which concentration may be lower than the concentration of Al in sublayer 30-10.

As may be understood from the foregoing example, a subset of the sublayers of layers 28-1 through 28-5 (e.g., sublayers 30-2, 30-4, 30-6, 30-8 and 30-10) have decreasing amounts of metal (e.g., Al) concentration from lower layers 28 of the top DBR 12 to upper layers 28 of the top DBR 12. Stated differently, the subset of the sublayers of layers 28-1 through 28-5 (e.g., sublayers 30-2, 30-4, 30-6, 30-8 and 30-10) have increasing amounts of metal (e.g., Al) concentration from upper layers 28 of the top DBR 12 to lower (or bottom) layers 28 of the top DBR 12. In this example, a subset of the sublayers of layers 28-6 through 28-8 (e.g., sublayers 30-12, 30-14 and 30-16) may have the same amount of metal (e.g., Al) concentration which may be less than the metal (e.g., Al) concentration of sublayer 30-10.

These examples of the top DBR 12 are strictly for the purpose of example and are not to be construed in a limiting sense. Moreover, throughout this disclosure and in an example, it is envisioned that some or all of the instances of Al in the various layers and/or sublayers may be replaced with any other metal(s) or combination of metal(s) suitable for use to form a VCSEL. In another example, Al may be used in some of layers and/or sublayers while said any other metal(s) or combination of metal(s) may be used in some or all of the other layers and/or sublayers.

In an example, the spreading layer 13 may be disposed atop of (e.g., in direct contact with) the topside of the top DBR 12. As is known in the art, the spreading layer 13 may aid in achieving uniform current distribution, which may aid in achieving uniform light emission while minimizing thermal issues with operation of the VCSEL which, in-turn, may contribute to the overall performance and reliability of the VCSEL. In an example, the spreading layer 13 may be formed from one or more sublayers of AlₓGa₁₋ₓAs, wherein x may be equal to 0.10±0.10 in each sublayer.

In an example, the passivation layer 14 may be disposed atop of (e.g., in direct contact with) the topside of the spreading layer 13 as a protective layer against moisture and particulate intrusion into the VCSEL from the topside of the VCSEL.

Finally, at a suitable time or times, the electrical contacts 16 and 16′ may be formed in contact with the topsides of the respective top DBR 12 and bottom DBR 4 for applying to the VCSEL a suitable electrical bias that causes the VCSEL to emit light, e.g., laser light. The locations and shapes of the electrical contacts 16 and 16′ in FIG. 1 is not to be construed in a limiting sense.

At a suitable time during formation or manufacturing thereof, the VCSEL may be exposed to an oxidizing environment which may cause the current confinement layer 10 to form and define the region of low resistance to current flow 22 surrounded by the region of high resistance to current flow 24 as described above. The oxidizing environment may also cause the metal (e.g., Al) forming at least sublayers 30-2, 30-4, 30-6, 30-8, 30-10, 30-12, 30-14, and 30-16 of the top DBR 12 to oxidize (as shown by the dark shading in FIG. 1) from their respective outer edges (i.e., from the side surface of the top DBR 12) inwardly thereby forming the graded-oxide stair step or staircase profile shown in FIG. 1 due to the different concentrations of Al in sublayers 30-2, 30-4, 30-6, 30-8, and 30-10.

In FIG. 1, the portions of sublayers 30-2, 30-4, 30-6, 30-8, 30-10, 30-12, 30-14, and 30-16 that are oxidized by the oxidizing environment are shown by dark shading while the portions of sublayers 30-2, 30-4, 30-6, 30-8, 30-10, 30-12, 30-14, and 30-16 that are not oxidized by the oxidizing environment are not shaded.

Moreover, with continuing reference to the top DBR 12, the oxidizing environment may also cause the metal (e.g., Al) forming at least sublayers 30-12, 30-14 and 30-16, which have the same or substantially the same metal (e.g., Al) concentration which is lower than the metal (e.g., Al) concentration in at least sublayer 30-10, to oxidize inwardly to a uniform or substantially uniform extent or distance from their respective outside edges. Because of the lower metal (e.g., Al) concentrations in sublayers 30-12, 30-14 and 30-16, these sublayers will oxidize inwardly to a lesser extent than any of layers 30-2, 30-4, 30-6, 30-8, and 30-10.

In the example VCSEL shown in FIG. 1, the un-oxidized portion (unshaded in the figure) of sublayer 30-2 is smaller (e.g., has a smaller diameter) than the un-oxidized portion of sublayer 30-4. The un-oxidized portion (unshaded in the figure) of sublayer 30-4 is smaller (e.g., has a smaller diameter) than the un-oxidized portion of sublayer 30-6. The un-oxidized portion (unshaded in the figure) of sublayer 30-6 is smaller (e.g., has a smaller diameter) than the un-oxidized portion of sublayer 30-8. The un-oxidized portion (unshaded in the figure) of sublayer 30-8 is smaller (e.g., has a smaller diameter) than the un-oxidized portion of sublayer 30-10. Finally, in this example, the un-oxidized portion (unshaded in the figure) of sublayer 30-10 is smaller (e.g., has a smaller diameter) than the un-oxidized portions of sublayers 30-12, 30-14, and 30-16.

Stated differently, the un-oxidized portions (unshaded in the figure) of sublayers 30-12, 30-14, and 30-16 have the same size or substantially the same size (e.g., diameter) which is larger than the size of the un-oxidized portion of sublayer 30-10, which has an un-oxidized portion that is larger than the size of the un-oxidized portion of sublayer 30-8, which has an un-oxidized portion that is larger than the size of the un-oxidized portion of sublayer 30-6, which has an un-oxidized portion that is larger than the size of the un-oxidized portion of sublayer 30-4, which has an un-oxidized portion that is larger than the size of the un-oxidized portion of sublayer 30-2.

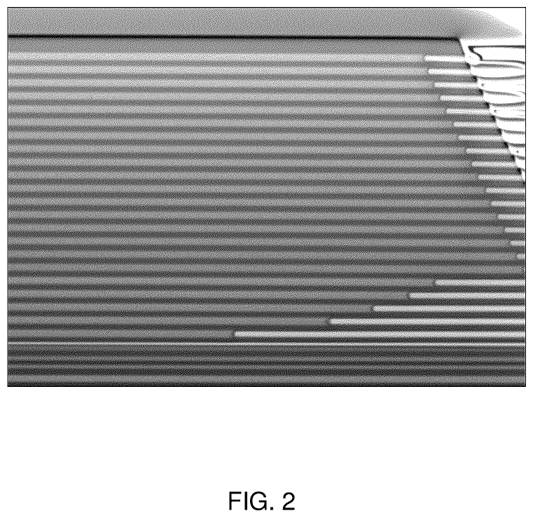

FIG. 2 shows an SEM image of a portion of a section of an example VCSEL in accordance with the principles of the present disclosure including, among other things, graded metal-oxide layers having the stair step or staircase profile.

In all of the foregoing examples, the amount or percentage of Al, Ga, and/or As in each layer and/or sublayer may be selected as may be deemed suitable and/or desirable by one skilled in the art for a particular application. Moreover, the amount or percentage of Al, Ga, and/or As in each layer or sublayer may vary a due to manufacturing tolerances. Accordingly, in all of the foregoing examples, the amount or percentage of Al, Ga, and/or As in each layer or sublayer is strictly for the purpose of this disclosure and is not to be construed in a limiting sense.

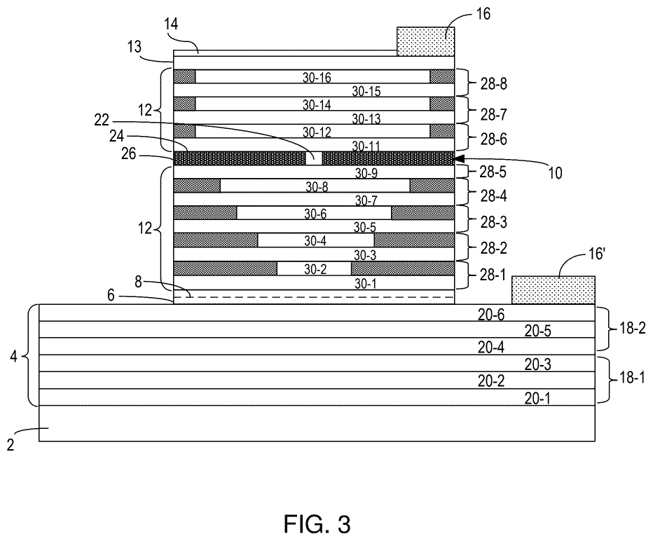

With reference to FIG. 3 and with continuing reference to FIG. 1, another example VCSEL (shown in FIG. 3) in accordance with the principles of the present disclosure may be the same as the example VCSEL shown in FIG. 1 except as follows: instead of the current confinement layer 10 cavity layer 6 being disposed between the cavity layer 6 and sublayer 30-1 (as shown in FIG. 1), in FIG. 3 the current confinement layer 10 is disposed between sublayers 30-9 and 30-11 in replacement of sublayer 30-10 which is eliminated, and sublayer 30-1 is disposed atop of and in direct contact with the cavity layer 6.

In this example, layer 28-5 may be comprised of a single sublayer 30-9 of p or n-type AlGaAs (as shown in FIG. 3) or multiple sublayers of p or n-type AlGaAs of the same or different thicknesses.

In FIG. 3, layers 28-1 through 28-5 of the upper DRB 12 may be separated from layers 28-6 through 28-9 of the upper DRB 12 by the current confinement layer 10.

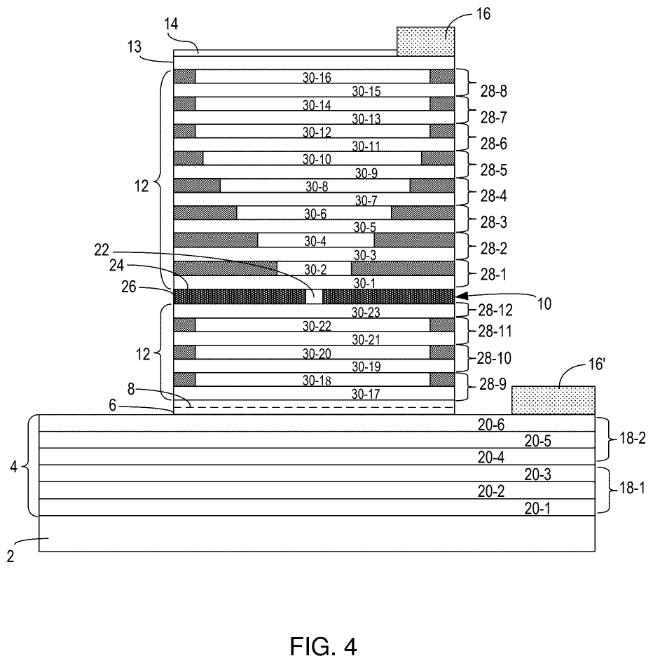

With reference to FIG. 4 and with continuing reference to FIG. 1, another example VCSEL (shown in FIG. 4) in accordance with the principles of the present disclosure may be the same as the example VCSEL shown in FIG. 1 except as follows: new layers 28-9 through 28-12 are disposed between the cavity layer 6 and the current confinement layer 10, wherein new layers 28-9 through 28-11 are the same as layers 28-6 through 28-8, respectively, and layer 28-12 is same as layer 30-1, for example.

### In an Example:

layer 28-9 may be comprised of sublayers 30-17 and 30-18 of p or n-type AlGaAs of the same or different thicknesses;
layer 28-10 may be comprised of sublayers 30-19 and 30-20 of p or n-type AlGaAs of the same or different thicknesses;
layer 28-11 may be comprised of sublayers 30-21 and 30-22 of p or n-type AlGaAs of the same or different thicknesses; and layer 28-12 may be comprised of a single sublayer 30-23 of p or n-type AlGaAs of the same or different thicknesses (shown in FIG. 4) or multiple sublayers of p or n-type AlGaAs of the same or different thicknesses.

In FIG. 4, layers 28-9 through 28-12 may comprise part of the upper DRB 12 that are separated from layers 28-1 through 28-8 of the upper DRB 12 by the current confinement layer 10.

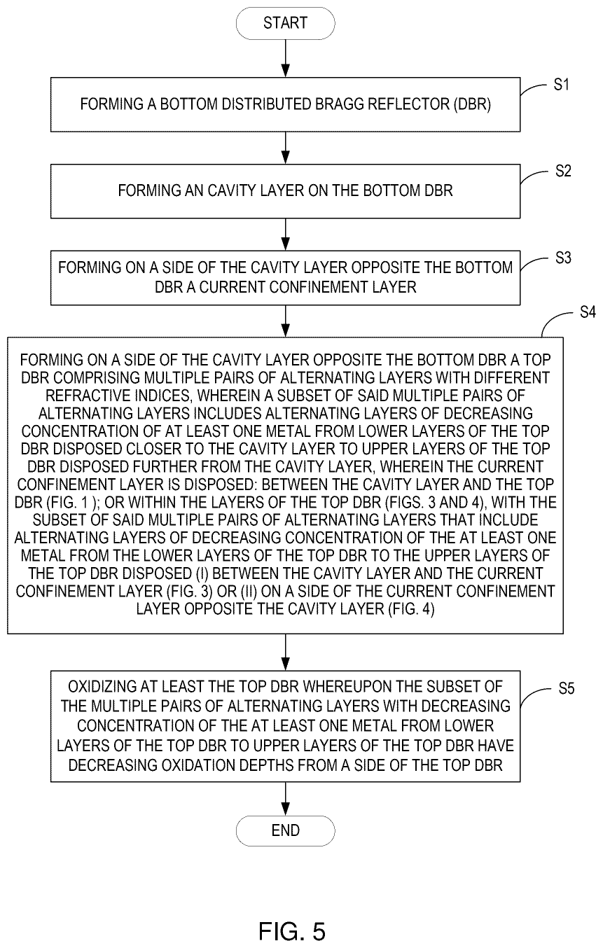

With reference to FIG. 5, a method of forming the example VCSEL in accordance with the principles of the present disclosure including, among other things, graded metal-oxide layers having the stair step or staircase profile may include step S1 forming a bottom Distributed Bragg Reflector (DBR) 4; step S2 forming a cavity layer 6 on the bottom DBR 4; step S3 forming on a side of the cavity layer 6 opposite the bottom DBR a current confinement layer 10; and step S4 forming on a side of the cavity layer 6 opposite the bottom DBR 4 a top DBR 12 comprising multiple pairs of alternating layers with different refractive indices, wherein a subset of said multiple pairs of alternating layers includes alternating layers of decreasing concentration of at least one metal from lower layers of the top DBR 12 disposed closer to the cavity layer 6 to upper layers of the top DBR disposed further from the cavity layer 6, wherein the current confinement layer 10 is disposed: between the cavity layer 6 and the top DBR 12 (FIG. 1) ; or within the layers of the top DBR 12 (FIGS. 3 and 4), with the subset of said multiple pairs of alternating layers that include alternating layers of decreasing concentration of at the least one metal from the lower layers of the top DBR 12 to the upper layers of the top DBR 12 is disposed (i) between the cavity layer 6 and the current confinement layer 10 (FIG. 3) or (ii) on a side of the current confinement layer opposite the cavity layer (FIG. 4).

The method may further include step S5 oxidizing at least the top DBR whereupon the subset of the multiple pairs of alternating layers of the decreasing concentration of the at least one metal from the lower layers of the top DBR to the upper layers of the top DBR have decreasing oxidation depths from a side surface of the top DBR.

Other non-limiting examples or aspects of this disclosure are set forth in the following illustrative and exemplary numbered clauses:

Clause 1: A vertical cavity surface-emitting laser (VCSEL) includes a stack of semiconductor layers comprising: a bottom Distributed Bragg Reflector (DBR); a cavity layer on the bottom DBR; a current confinement layer; and a top DBR on a side of the cavity layer opposite the bottom DBR, wherein the top DBR comprises multiple pairs of alternating layers with different refractive indices, wherein a subset of said multiple pairs of alternating layers includes alternating layers of decreasing concentration of at least one metal from lower layers of the top DBR disposed closer to the cavity layer to upper layers of the top DBR disposed further from the cavity layer, wherein the current confinement layer is disposed: between the cavity layer and the top DBR; or within the layers of the top DBR, with the subset of said multiple pairs of alternating layers that include alternating layers of decreasing concentration of the at least one metal from the lower layers of the top DBR to the upper layers of the top DBR is disposed (i) between the cavity layer and the current confinement layer or (ii) on a side of the current confinement layer opposite the cavity layer.

Clause 2: The VCSEL of clause1, wherein each layer of the top DBR may be comprised of AlGaAs.

Clause 3: The VCSEL of clause 1 or 2, wherein the at least one metal may be Aluminum.

Clause 4: The VCSEL of any one of clauses 1-3, wherein the subset of the multiple pairs of alternating layers of the decreasing concentration of the at least one metal from the lower layers of the top DBR to the upper layers of the top DBR may have decreasing oxidation depths from a side surface of the top DBR.

Clause 5: The VCSEL of any one of clauses 1-4, wherein the decreasing oxidation depths of the subset of the multiple pairs of alternating layers of the decreasing concentration of the at least one metal from the lower layers of the top DBR to the upper layers of the top DBR may form a graded-oxide stair step or staircase profile.

Clause 6: The VCSEL of any one of clauses 1-5, wherein the subset of the multiple pairs of alternating layers with of the decreasing concentration of the at least one metal from the lower layers of the top DBR to the upper layers of the top DBR may include at least three layers of the decreasing concentration of the at least one metal.

Clause 7: The VCSEL of any one of clauses 1-6, wherein each layer of the top DBR may be comprised of one or more sublayers.

Clause 8: The VCSEL of any one of clauses 1-8, whereupon the pairs of layers of the top DBR may comprise, from the lower layers of the top DBR to the upper layers of the top DBR: a first pair of layers including a lower layer of AlₓGa₁₋ₓAs and an upper layer of Al_{y}Ga_{1-y}As; a second pair of layers including a lower layer of AlₓGa₁₋ₓAs and an upper layer of Al_{y1}Ga_{1-y1}As; and a third pair of layers including a lower layer of AlₓGa₁₋ₓAs and an upper layer of Al_{y2}Ga_{1-y2}As, wherein y>x and y>y1 >y2.

Clause 9: The VCSEL of any one of clauses 1-8, whereupon the pairs of layers of the top DBR may further comprise, from the lower layers of the top DBR to the upper layers of the top DBR: a fourth pair of layers including a lower layer of AlₓGa₁₋ₓAs and an upper layer of Al_{y3}Ga_{1-y3}As; and a fifth pair of layers including a lower layer of AlₓGa₁₋ₓAs and an upper layer of Al_{y4}Ga_{1-y4}As, wherein y2>y3>y4.

Clause 10: The VCSEL of any one of clauses 1-9, wherein: x may be between 0 and 0.30; y may be between 0.70 and 0.95; y1 may be between 0.70 and 0.95; y2 may be between 0.70 and 0.95; y3 may be between 0.70 and 0.95; and y4 may be between 0.70 and 0.95. As noted above, all ranges disclosed herein are to be understood to encompass the beginning and ending range values and any and all subranges subsumed therein.

Clause 11: The VCSEL of any one of clauses 1-10, may further comprise: a top contact on the top DBR; and bottom contact on the bottom DBR.

Clause 12: A method of forming a vertical cavity surface-emitting laser (VCSEL) may comprise: (a) forming a bottom Distributed Bragg Reflector (DBR); (b) forming an cavity layer on the bottom DBR; (c) forming on a side of the cavity layer opposite the bottom DBR a current confinement layer; and (d) forming on a side of the current confinement layer opposite the bottom DBR a top DBR comprising multiple pairs of alternating layers with different refractive indices, wherein a subset of said multiple pairs of alternating layers includes alternating layers of decreasing concentration of at least one metal from lower layers of the top DBR disposed closer to the cavity layer to upper layers of the top DBR disposed further from the cavity layer, wherein the current confinement layer is disposed: between the cavity layer and the top DBR; or within the layers of the top DBR, with the subset of said multiple pairs of alternating layers that include alternating layers of decreasing concentration of the at least one metal from the lower layers of the top DBR to the upper layers of the top DBR is disposed (i) between the cavity layer and the current confinement layer or (ii) on a side of the current confinement layer opposite the cavity layer.

Clause 13: The method of clause 12, may further comprise: (e) oxidizing at least the top DBR whereupon the subset of the multiple pairs of alternating layers of the decreasing concentration of the at least one metal from the lower layers of the top DBR to the upper layers of the top DBR have decreasing oxidation depths from a side surface of the top DBR.

Clause 14: The method of clause 12 or 13, wherein the decreasing oxidation depths of the subset of the multiple pairs of alternating layers of the decreasing concentration of the at least one metal from the lower layers of the top DBR to the upper layers of the top DBR form a graded-oxide stair step or staircase profile.

Clause 15. The method of any one of clauses 12-14, wherein the subset of the multiple pairs of alternating layers of the decreasing concentration of the at least one metal from the lower layers of the top DBR to the upper layers of the top DBR includes at least three layers of the decreasing concentration of the at least one metal.

Clause 16: The method of any one of clauses 12-15, wherein each layer of the top DBR may comprise one or more sublayers.

Clause 17: The method of any one of clauses 12-16, whereupon the pairs of layers of the top DBR may comprise, from the lower layers of the top DBR to the upper layers of the top DBR: a first pair of layers including a lower layer of AlₓGa₁₋ₓAs and an upper layer of Al_{y}Ga_{1-y}As; a second pair of layers including a lower layer of AlₓGa₁₋ₓAs and an upper layer of Al_{y1}Ga_{1-y1}As; and a third pair of layers including a lower layer of AlₓGa₁₋ₓAs and an upper layer of Al_{y2}Ga_{1-y2}As, wherein y>x and y>y1 >y2.

Clause 18: the method of any one of clauses 12-17, whereupon the pairs of layers of the top DBR may further comprise, from the lower layers of the top DBR to the upper layers of the top DBR: a fourth pair of layers including a lower layer of AlₓGa₁₋ₓAs and an upper layer of Al_{y3}Ga_{1-y3}As; and a fifth pair of layers including a lower layer of AlₓGa₁₋ₓAs and an upper layer of Al_{y4}Ga_{1-y4}As, wherein y2>y3>y4.

Clause 19. The method of any one of clauses 12-18, wherein: x may be between 0 and 0.30; y may be between 0.70 and 0.95; y1 may be between 0.70 and 0.95; y2 may be between 0.70 and 0.95; y3 may be between 0.70 and 0.95; and y4 may be between 0.70 and 0.95. As noted above, all ranges disclosed herein are to be understood to encompass the beginning and ending range values and any and all subranges subsumed therein.

Clause 20. A vertical cavity surface-emitting laser (VCSEL) including a stack of semiconductor layers comprising: a bottom Distributed Bragg Reflector (DBR); a cavity layer on the bottom DBR; a current confinement layer on a side of the cavity layer opposite the bottom DBR; and a top DBR on a side of the cavity layer opposite the bottom DBR, wherein the top DBR comprises multiple pairs of alternating layers with different refractive indices, wherein a subset of said multiple pairs of alternating layers includes alternating layers of increasing metal concentration from upper layers of the top DBR to bottom layers of the top DBR.

Although this disclosure has been described in detail for the purpose of illustration based on what is currently considered to be the most practical and preferred embodiments, it is to be understood that such detail is solely for that purpose and that the disclosure is not limited to the disclosed embodiments, but, on the contrary, is intended to cover modifications and equivalent arrangements that are within the spirit and scope of the appended claims. For example, it is to be understood that the present disclosure contemplates that, to the extent possible, one or more features of any embodiment can be combined with one or more features of any other embodiment.

What is claimed is:

1. A vertical cavity surface-emitting laser (VCSEL) including a stack of semiconductor layers comprising:
a bottom Distributed Bragg Reflector (DBR);
a cavity layer on the bottom DBR;
a current confinement layer; and
a top DBR on a side of the cavity layer opposite the bottom DBR, wherein the top DBR comprises multiple pairs of alternating layers with different refractive indices, wherein a subset of said multiple pairs of alternating layers includes alternating layers of decreasing concentration of at least one metal from lower layers of the top DBR disposed closer to the cavity layer to upper layers of the top DBR disposed further from the cavity layer, wherein the current confinement layer is disposed:
between the cavity layer and the top DBR; or
within the layers of the top DBR, with the subset of said multiple pairs of alternating layers that include alternating layers of decreasing concentration of the at least one metal from the lower layers of the top DBR to the upper layers of the top DBR is disposed (i) between the cavity layer and the current confinement layer or (ii) on a side of the current confinement layer opposite the cavity layer.

2. The VCSEL of claim 1, wherein each layer of the top DBR is comprised of AlGaAs.

3. The VCSEL of claim 1, wherein the at least one metal is Aluminum.

4. The VCSEL of claim 1, wherein the subset of the multiple pairs of alternating layers of the decreasing concentration of the at least one metal from the lower layers of the top DBR to the upper layers of the top DBR have decreasing oxidation depths from a side of the top DBR.

5. The VCSEL of claim 4, wherein the decreasing oxidation depths of the subset of the multiple pairs of alternating layers of the decreasing concentration of the at least one metal from the lower layers of the top DBR to the upper layers of the top DBR form a graded-oxide stair step or staircase profile.

6. The VCSEL of claim 1, wherein the subset of the multiple pairs of alternating layers of the decreasing concentration of the at least one metal from the lower layers of the top DBR to the upper layers of the top DBR includes at least three layers of the decreasing concentration of the at least one metal.

7. The VCSEL of claim 1, wherein each layer of the top DBR comprises one or more sublayers.

8. The VCSEL of claim 1, whereupon the pairs of layers of the top DBR comprise, from the lower layers of the top DBR to the upper layers of the top DBR:
a first pair of layers including a lower layer of AlₓGa₁₋ₓAs and an upper layer of Al_{y}Ga_{1-y}As;
a second pair of layers including a lower layer of AlₓGa₁₋ₓAs and an upper layer of Al_{y1}Ga_{1-y1}As; and
a third pair of layers including a lower layer of Al ₓGa₁₋ₓAs and an upper layer of Al_{y2}Ga_{1-y2}As, wherein y>x and y>y1>y2.

9. The VCSEL of claim 8, whereupon the pairs of layers of the top DBR further comprise, from the lower layers of the top DBR to the upper layers of the top DBR:
a fourth pair of layers including a lower layer of Al ₓGa₁₋ₓAs and an upper layer of Al_{y3}Ga_{1-y3}As; and
a fifth pair of layers including a lower layer of AlₓGa₁₋ₓAs and an upper layer of Al_{y4}Ga_{1-y4}As, wherein y2>y3>y4.

10. The VCSEL of claim 9, wherein:
0≤x≤0.30;
0.70≤y≤0.95;
0.70≤y1≤0.95;
0.70≤y2≤0.95;
0.70≤y3≤0.95; and
0.70≤y4≤0.95.

11. The VCSEL of claim 1, further comprising:
a top contact on the top DBR; and
bottom contact on the bottom DBR.

12. A method of forming a vertical cavity surface-emitting laser (VCSEL) comprising:
(a) forming a bottom Distributed Bragg Reflector (DBR);
(b) forming a cavity layer on the bottom DBR;
(c) forming on a side of the cavity layer opposite the bottom DBR a current confinement layer; and
(d) forming on a side of the cavity layer opposite the bottom DBR a top DBR comprising multiple pairs of alternating layers with different refractive indices, wherein a subset of said multiple pairs of alternating layers includes alternating layers of decreasing concentration of at least one metal from lower layers of the top DBR disposed closer to the cavity layer to upper layers of the top DBR disposed further from the cavity layer, wherein the current confinement layer is disposed:
between the cavity layer and the top DBR; or
within the layers of the top DBR, with the subset of said multiple pairs of alternating layers that include alternating layers of decreasing concentration of the at least one metal from the lower layers of the top DBR to the upper layers of the top DBR is disposed (i) between the cavity layer and the current confinement layer or (ii) on a side of the current confinement layer opposite the cavity layer.

13. The method of claim 12, further comprising:
(e) oxidizing at least the top DBR whereupon the subset of the multiple pairs of alternating layers of the decreasing concentration of the at least one metal from the lower layers of the top DBR to the upper layers of the top DBR have decreasing oxidation depths from a side of the top DBR.

14. The method of claim 13, wherein the decreasing oxidation depths of the subset of the multiple pairs of alternating layers of the decreasing concentration of the at least one metal from the lower layers of the top DBR to the upper layers of the top DBR form a graded-oxide stair step or staircase profile.

15. The method of claim 12, wherein the subset of the multiple pairs of alternating layers of the decreasing concentration of the at least one metal from the lower layers of the top DBR to the upper layers of the top DBR includes at least three layers of the decreasing concentration of the at least one metal.

16. The method of claim 12, wherein each layer of the top DBR comprises one or more sublayers.

17. The method of claim 12, whereupon the pairs of layers of the top DBR comprise, from the lower layers of the top DBR to the upper layers of the top DBR:
a first pair of layers including a lower layer of AlₓGa₁₋ₓAs and an upper layer of Al_{y}Ga_{1-y}As;
a second pair of layers including a lower layer of AlₓGa₁₋ₓAs and an upper layer of Al_{y1}Ga_{1-y1}As; and
a third pair of layers including a lower layer of Al ₓGa₁₋ₓAs and an upper layer of Al_{y2}Ga_{1-y2}As, wherein y>x and y>y1>y2.

18. The method of claim 17, whereupon the pairs of layers of the top DBR further comprise, from the lower layers of the top DBR to the upper layers of the top DBR:
a fourth pair of layers including a lower layer of Al ₓGa₁₋ₓAs and an upper layer of Al_{y3}Ga_{1-y3}As; and
a fifth pair of layers including a lower layer of AlₓGa₁₋ₓAs and an upper layer of Al_{y4}Ga_{1-y4}As, wherein y2>y3>y4.

19. The method of claim 18, wherein:
0≤x≤0.30;
0.70≤y≤0.95;
0.70≤y1≤0.95;
0.70≤y2≤0.95;
0.70≤y3≤0.95; and
0.70≤y4≤0.95.

20. A vertical cavity surface-emitting laser (VCSEL) including a stack of semiconductor layers comprising:
a bottom Distributed Bragg Reflector (DBR);
a cavity layer on the bottom DBR;
a current confinement layer on a side of the cavity layer opposite the bottom DBR;
and a top DBR on a side of the cavity layer opposite the bottom DBR, wherein the top DBR comprises multiple pairs of alternating layers with different refractive indices, wherein a subset of said multiple pairs of alternating layers includes alternating layers of increasing metal concentration from upper layers of the top DBR to bottom layers of the top DBR.
